(19) United States
(12) Patent Application Publication
(10) Pub. No.: US 2006/0255381 A1
(43) Pub. Date: Nov. 16, 2006

(54) Pixel with gate contacts over active region and method of forming same

(75) Inventor: Jeffrey A. McKee, Meridian, ID (US)

Correspondence Address: DICKSTEIN SHAPIRO LLP, 1825 EYE STREET NW, Washington, DC, 20006-5403, US

(73) Assignee: Micron Technology, Inc.

(21) Appl. No.: 11/125,246

(22) Filed: May 10, 2005

(51) Int. Cl. H01L 31/062

(52) U.S. Cl. 257/292

(57) ABSTRACT

The invention relates to a pixel and imager device, and method of forming the same, where the contacts to the gates of the transistors of the pixel are located over the active region of the pixel, e.g., the channel regions of the transistor gates. The location of the transistor gate contacts makes for a denser circuit for the pixel and allows the photosensor region to be increased in size relative to the pixel size.

### BACKGROUND

1. Field of the Invention

The invention relates to imager technology. In particular, the invention relates to imager devices with a denser circuitry configuration.

2. Description of the Related Art

Exemplary CMOS imaging circuits, processing steps thereof, and detailed descriptions of the functions of various CMOS elements of an imaging circuit are described, for example, in U.S. Pat. No. 6,140,630, U.S. Pat. No. 6,376,868, U.S. Pat. No. 6,310,366, U.S. Pat. No. 6,326,652, U.S. Pat. No. 6,204,524, and U.S. Pat. No. 6,333,205, each assigned to Micron Technology, Inc. The disclosures of the forgoing patents are hereby incorporated by reference in their entirety.

FIG. 1 illustrates a top-down view of a conventional CMOS pixel 10 having a photodiode 14 in a substrate 12 as a photoconversion device. The pixel 10 includes a transfer gate 16, which, with the photodiode 14 and a floating diffusion region 24, forms a transfer transistor. Also included is a reset gate 18, which gates a reset voltage (Vₐₐ) applied to an active area 26 to floating diffusion region 24 so that the floating diffusion region 24 resets. The photodiode 14 may also be reset when both the reset gate 18 and transfer gate 16 are turned on. Also included is a source follower gate 20, which is electrically coupled 25 to the floating diffusion region 24 and which is part of a source follower transistor formed by active area 26, which is connected to voltage source (Vₐₐ), and an active area 28 associated with a row select gate 22. The row select gate 22 is operated as part of a row select transistor, which connects active area 28 and active area 30, which is connected to the pixel output for reading the pixel.

The source/drain regions of the transistors described above, the floating diffusion region, the channel regions under the gates and between the source/drain regions, and the photodiode region are defined as active areas of the pixel 10 because of their doping, which, in combination with the gate structures, define active electronic devices. As is shown in FIG. 1, in conventional pixel 10, the contacts 32, 34, 36, and 38 for the transistor gates 16, 18, 20, and 22 are positioned away from the active areas 24, 26, 28, and 30. This follows the commonly accepted belief that it is undesirable to chance etching through the thin gate electrodes of the circuitry over the active areas or position contacts too close to gate oxides, which may create non-functioning devices; therefore the contacts are not located over active areas.

It would be advantageous, as pixel pitch is scaled down, to reposition the transistor gate contacts so that the photodiode can remain a large as possible for photo-electric generation and enhanced quantum efficiency.

### SUMMARY

The invention relates to an imager pixel having a photoconversion device and transistor structures, wherein the contacts to the gates of the transistors of the pixel are over the active areas of the pixel. More specifically, one or more of the contacts can be over the channel regions of the transistors. This arrangement permits the circuitry of a pixel array to be more densely packed, which allows the pitch of the pixel to be scaled down while the photoconversion device, e.g., photodiode, remains relatively large.

These and other features of the invention will be better understood from the following detailed description, which is provided in connection with the accompanying drawings.

### BRIEF DESCRIPTION OF THE DRAWINGS

FIG. 1 is a top-down view of a conventional CMOS pixel cell.

FIG. 2 shows a CMOS pixel cell in accordance with an embodiment of the invention.

FIGS. 3-8 show stages of fabrication of a CMOS pixel cell as shown by FIG. 2 through lines a-a′ and b-b′ of FIG. 2.

FIG. 9 shows a CMOS pixel cell in accordance with an embodiment of the invention.

FIG. 10 shows a processor system incorporating at least one imager constructed in accordance with an embodiment of the invention.

### DETAILED DESCRIPTION

Although this invention will be described in terms of certain exemplary embodiments, other embodiments will be apparent to those of ordinary skill in the art, which also are within the scope of this invention. Accordingly, the scope of the invention is defined only by reference to the appended claims.

The term “substrate” or “wafer,” used interchangeably in the following description, may include any supporting structure including, but not limited, to a semiconductor substrate. A semiconductor substrate should be understood to include silicon-on-insulator (SOI), silicon-on-sapphire (SOS), doped and undoped semiconductors, epitaxial layers of silicon supported by a base semiconductor foundation, and other semiconductor structures; however, materials other than semiconductors can be used as well so long as they are suitable to support an integrated circuit. When reference is made to a substrate or wafer in the following description, previous process steps may have been utilized to form regions or junctions in or over a base semiconductor or foundation.

The term “pixel” refers to a photo-element unit cell containing a photoconversion device and associated transistors for converting electromagnetic radiation to an electrical signal. The pixels discussed herein are illustrated and described as 4T (4 transistors) pixel circuits for the sake of example only. It should be understood that the invention is not limited to a four transistor (4T) pixel, but may be used with other pixel arrangements having fewer (e.g., 3T) or more (e.g., 5T) than four transistors. Although the invention is described herein with reference to the architecture and fabrication of one or a limited number of pixels, it should be understood that this is representative of a plurality of pixels as typically would be arranged in an imager array having pixels arranged, for example, in rows and columns. In addition, although the invention is described below with reference to a pixel for a CMOS imager, the invention has applicability to other solid state imaging devices having pixels (e.g., a CCD or other solid state imager). The following detailed description is, therefore, not to be taken in a limiting sense, and the scope of the present invention is defined only by the appended claims.

The term “active region,” refers to the regions of the pixel in the substrate that are electrically active, typically made so by doping. The term “active region” includes the photodiode region, the source/drain regions, the floating diffusion region, and transistor channels of the pixel.

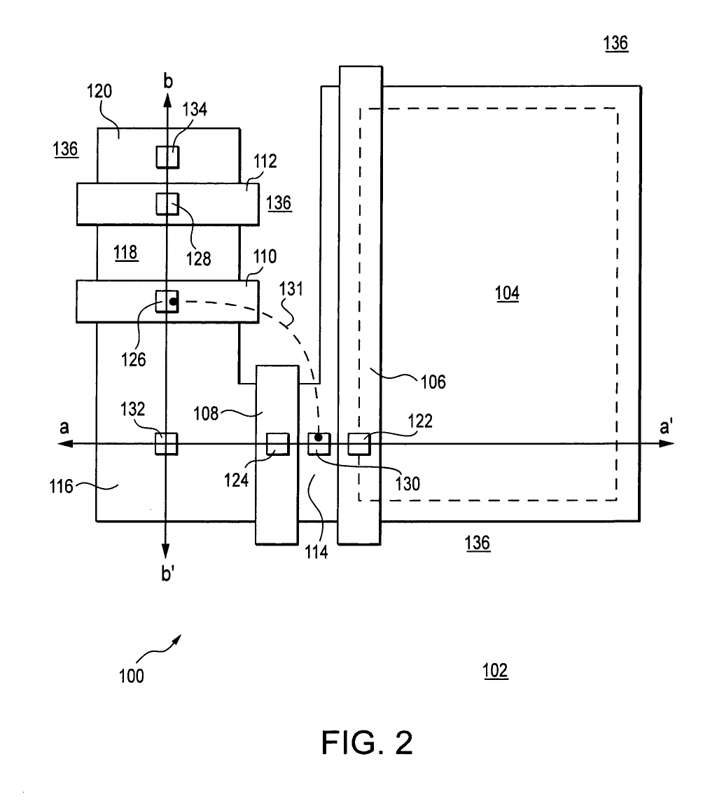

The invention will now be explained with reference to the accompanying figures wherein like reference numbers are used consistently for like features throughout the drawings. FIG. 2 shows an exemplary CMOS pixel 100 in accordance with an embodiment of the invention. The pixel 100 shown is fabricated in and over a semiconductor substrate 102. The pixel 100 can be isolated from other like pixels of an array by shallow trench isolation 136 (STI), which surrounds the active area of the pixel 100 as shown. Isolation using LOCOS (local oxidation of silicon) is also possible. The pixel 100 of this embodiment is a 4T pixel, meaning that the pixel's circuitry includes four transistors for operation; however, as indicated above, the invention is not limited to 4T pixels.

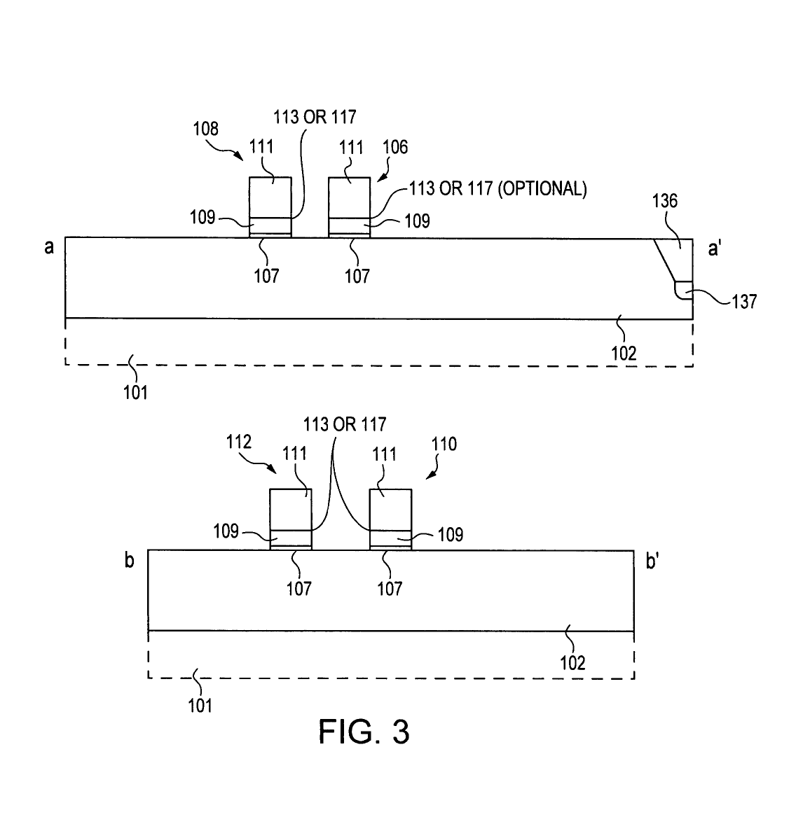

Still referring to FIG. 2, the pixel 100 has a photodiode 104 as a photoconversion device. The photodiode 104 is formed in the substrate 102 by forming layered doped regions of varying depths, as will be discussed in further detail with reference to FIGS. 3-8. Other types of photoconversion devices may be used as well, e.g., a photogate. A transfer transistor is associated with the photodiode 104. The transfer transistor includes a transfer gate 106 configured to gate charge across a channel region between the photodiode 104 and a floating diffusion region 114, which is a doped active area of the substrate 102. The floating diffusion region 114 is electrically connected (connection 131) to a gate 110 of a source follower transistor. The source follower transistor is electrically connected to a row select gate 112, configured to output a read signal from the pixel 100 at conductor 134. A reset transistor having a reset gate 108 electrically connected with a voltage source (e.g., Vₐₐ) is provided for resetting the floating diffusion region 114 after readout.

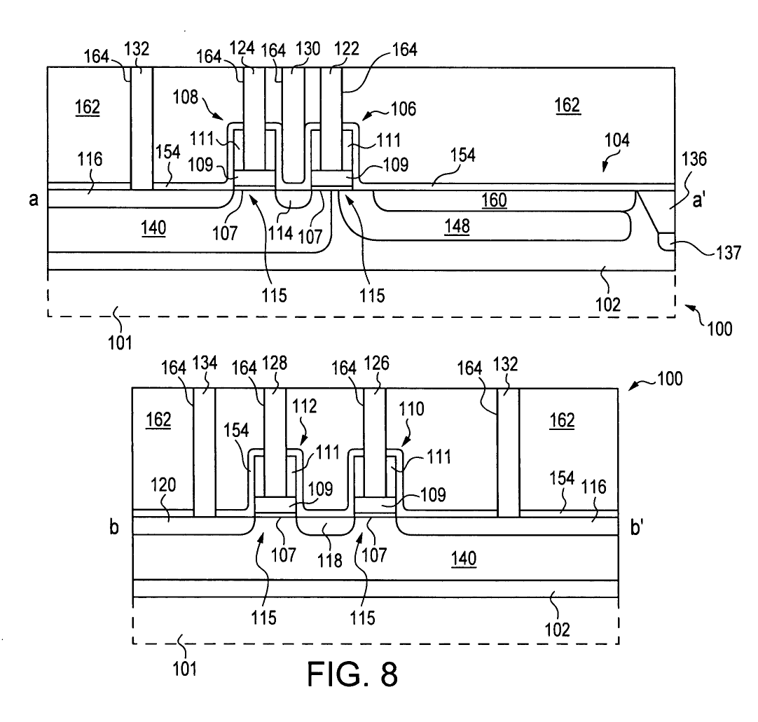

The pixel 100 has active regions associated with the photodiode 104, transfer gate 106, the reset gate 108, the source follower gate 110, and the row select gate 112. These active regions include the photodiode 104, floating diffusion region 114 and source/drain regions 116, 118, and 120, as well as the channel regions (see 115 of FIG. 8) of the substrate under the gates. Contacts 130, 132 and 134 from upper layer metallization layers are provided to these active regions and/or gate structures, typically as conductive plugs, which may be tungsten, titanium, or other conductive materials. Contact 130 connects with source follower gate 110. Contact 132 connects a voltage source (Vₐₐ) to source/drain region 116. Contact 134 connects with the output source drain region 120 of the row select transistor.

The pixel 100 also has contacts 122, 124, 126, and 128, to the transistor gates 106, 108, 110, and 112. Instead of positioning the transistor gate contacts in areas over STI regions or other non-active regions, here the contacts 122, 124, 126, 128 are positioned directly over the transistor gate channel regions of the active regions. Contact 122 goes directly to the transfer gate 106 over the active region which is between the photodiode 104 and floating diffusion region 114. Likewise, contact 124 goes directly to the reset gate 108 over the active region, contact 126 goes directly to the source follower gate 110 over the active region, and contact 134 goes directly to the row select gate 112 over the active region.

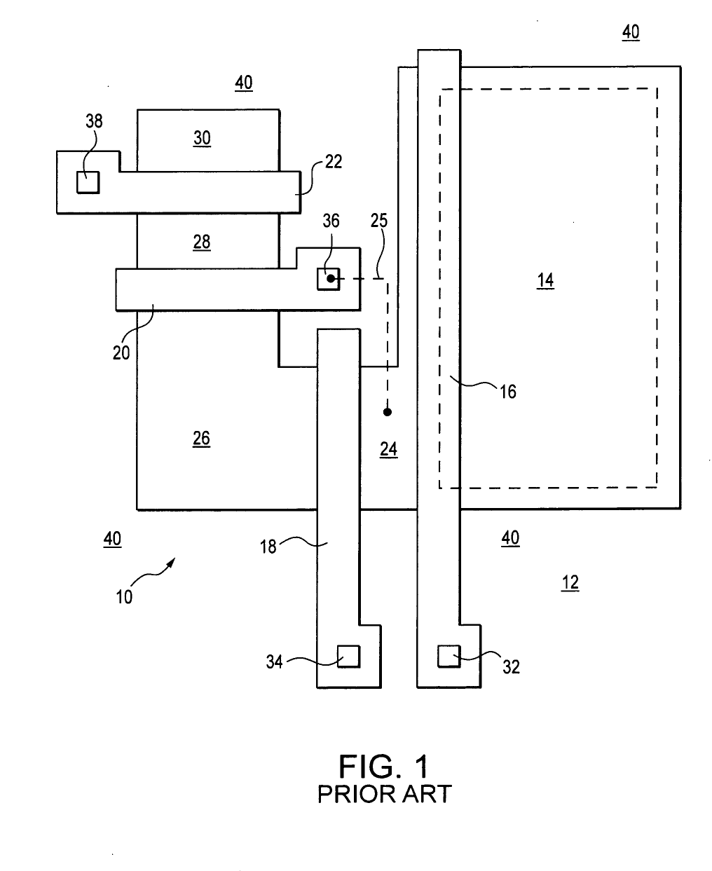

Locating contacts (122, 124, 126, and 128) in this way has not been previously considered possible for a variety of reasons. One reason has been that semiconductor integrated circuit scaling has resulted in conventional gate dimensions decreasing to the point (e.g., smaller than 0.11 μm to 0.095 μm wide) where targeting the gate with an etch to form a via opening in which a contact (e.g., typically no smaller than about 0.16 μm to 0.20 μm wide) could be deposited was not possible. This is why contact pads have been used in conventional pixel cells (see FIG. 1). Also, providing a contact over a channel region of a transistor has caused concern and been avoided because if the contact reaches or even comes too close to the gate oxide, the transistor will not function. The increasingly thin gate electrode layers of conventional designs in the art increases the likelihood of this. These reasons are why, until this invention, contacts to transistor gates of imager pixels have not been provided over the active region.

Locating the contacts over the active region, as provided by the invention as shown in FIG. 2, allows for a denser circuit for the pixel 100. This increased density allows for a larger photodiode 104 relative to the associated circuitry when the overall pixel 100 is scaled to smaller dimensions. The area of the substrate that in the prior art was used for locating gate contacts can now be occupied by the photodiode 104 or parts of adjacent pixels, and adjacent pixels can be positioned closer together, which allows for a greater density of pixels in an array. However, because the photoconversion device (e.g., photodiode 104) can stay the same size or increase in size to occupy space formerly occupied by gate contacts, the imager device maintains at least typical photo-sensitivity and photocharge generation capability.

The pixel 100 operates as a standard CMOS imager pixel. The photodiode 104 generates charge at a p-n junction (FIG. 8) when struck by light. The charge generated and accumulated at the photodiode 104 is gated to the floating diffusion region 114 by turning on the transfer gate 106. The charge at the floating diffusion region 114 is converted to a pixel output voltage signal by the source follower transistor, including gate 110 (connected to floating diffusion region 114 at contact 130), through source/drain region 118 and this output signal is gated by row select gate 112 to source/drain region 120 and is output at contact 134 to read circuitry (not shown). After the signal is read out of the pixel 100, the reset gate 108 and transfer gate 106 can be activated to connect a voltage source at contact 132 to the floating diffusion region 114 and photodiode 104 to reset the pixel 100.

FIGS. 3-8 show cross sections of a pixel 100 as shown in FIG. 2 at various stages of fabrication. The figures generally show sequential steps, which may be utilized to form a pixel 100; however, other or additional processing steps may be used also. Now referring to FIG. 3, a substrate region 102 is provided. The substrate 102 region is typically silicon, though other semiconductor substrates can be used. Preferably, substrate 102 is formed over another substrate region 101, which can have a different dopant concentration from the overlying region 102. In such an embodiment, substrate region 102 can be grown as an epi-layer over a supporting silicon substrate region 101.

Shallow trench isolation (STI) (or LOCOS if desired) is performed to form STI regions 136, which are typically an oxide and serve to electrically isolate individual pixels, including pixel 100, from one other. STI processing is well known in the art and standard processing techniques may be used. A region 137 of the substrate 102 under the STI trench may be doped to improve electrical isolation.

Over the substrate, the transfer gate 106, reset gate 108, source follower gate 110, and row select gate 112 are formed. These gates may be fabricated by forming a gate oxide 107 over the substrate 102, a conductive layer 109 over the gate oxide 107, and an insulating layer 111 over the conductive layer 109. The gate oxide 107 is typically silicon dioxide, but may be other materials as well. The conductive layer 109 is typically doped polysilicon, but may be other conductive materials as well. The insulating layer 111 is typically a nitride or TEOS (Tetraethyl Orthosilicate oxide), but may be other insulating materials as well. These layers 107, 109, and 111, are patterned with a photoresist mask and etched to leave gate stacks as shown in FIG. 3.

Because the gate contacts 122, 124, 126, and 128 (FIG. 2) are positioned over the transistor gates (106, 108, 110, and 112) and active region of the pixel 100 (FIG. 2), certain adjustments are preferred in the gates 106, 108, 110, and 112 as compared to conventional pixel designs. The gates 106, 108, 110, and 112 are formed to be wider and thicker than conventional CMOS pixel gates. The gates 106, 108, 110, and 112 are preferably at least about 0.30 μm wide to provide a suitable target for etching thereto in subsequent fabrication steps, since no larger contact pad is provided. Also, because the gates 106, 108, 110, and 112 are etched over the gate channel regions 115 and because it is not desirable to have the gate contacts 122, 124, 126, and 128 (FIG. 2) too close to the gate oxide 107, the conductive layer 109 is preferably made thicker (i.e., its height over the substrate surface) than conventional CMOS pixel gates. The conductive layer 109 has a thickness of at least about 0.10 μm, which is about twice that of a conventional layer used for an imager gate. In addition to making the gates conductive layers 109 thicker, it is also possible to optionally incorporate one or more of the following features into the gates to assist in preventing over etching: (1) a nitride/oxide stop layer 113 may be included at the conductive layer 109; and (2) a metal layer may be formed over the conductive layer 109 and be annealed so that the resultant silicide 117 acts as an etch stop.

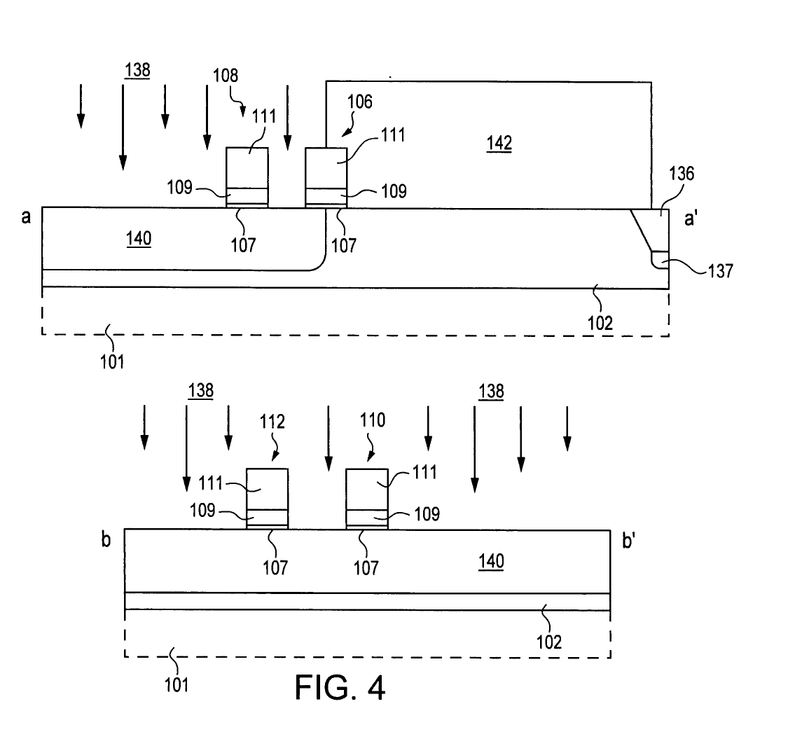

Now referring to FIG. 4, this figure shows the wafer cross-section shown in FIG. 3 at a subsequent stage of fabrication. A photoresist mask 142 is formed over the substrate 102 to protect the region that will become the photodiode 104 while exposing the substrate 102 surfaces proximate the transistor gates 106, 108, 110, and 112. A p-type dopant 138, e.g., boron, is implanted into the substrate 102 to form a p-well 140 therein.

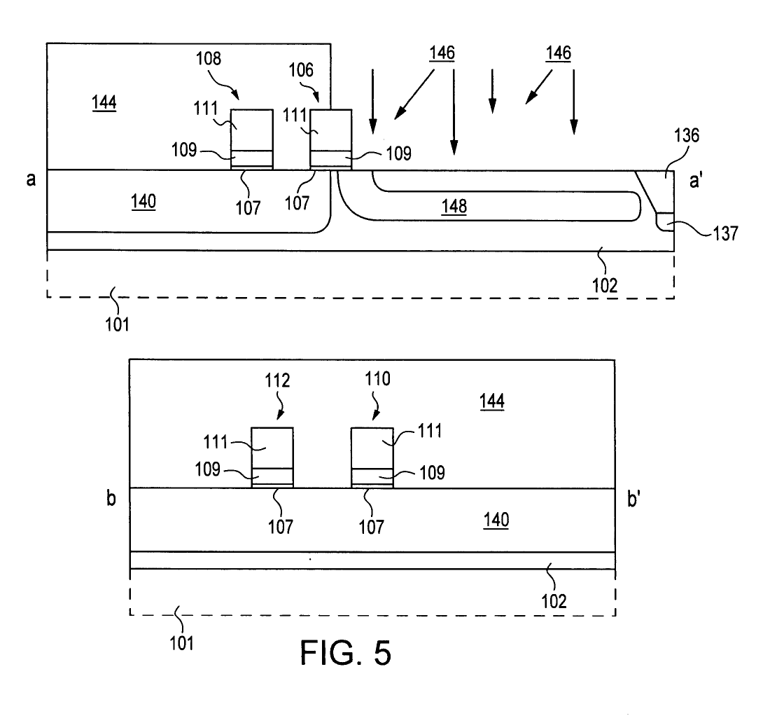

Now referring to FIG. 5, this figure shows the wafer cross-section shown in FIG. 4 at a subsequent stage of fabrication. After forming the p-well 140, the photoresist mask 142 is removed and another photoresist mask 144 is formed over the p-well 140 region of the substrate 102 to expose the surface of the substrate 102 where the photodiode 104 will be formed (FIG. 2). An n-type dopant 146, e.g., phosphorus, is implanted into the substrate 102 (directly there-into and at an angle thereto as shown) to form an n-type doped region 148. This n-type region 148 will form a charge accumulation portion of the photodiode 102 (FIG. 2).

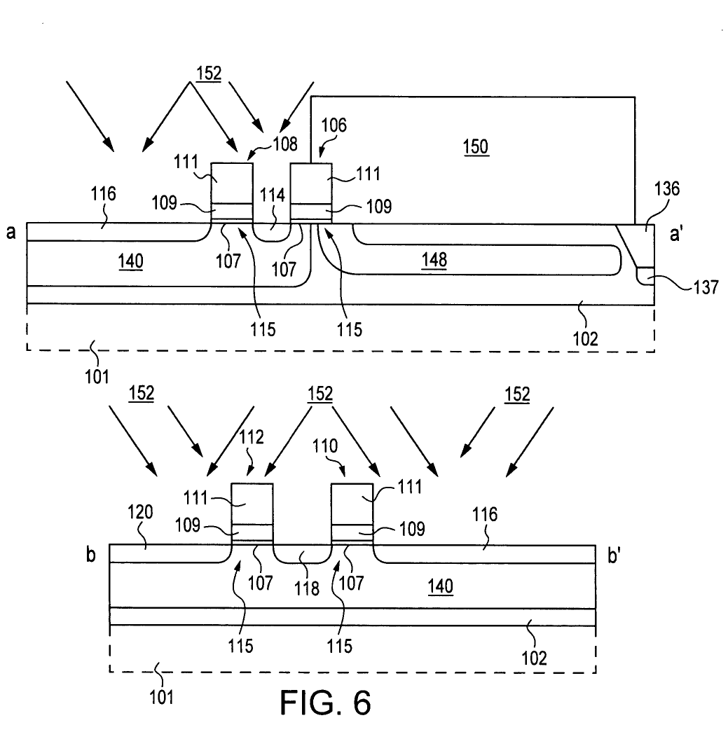

Now referring to FIG. 6, this figure shows the wafer cross-section shown in FIG. 5 at a subsequent stage of fabrication. After removing photoresist 144, another photoresist mask 150 is formed to protect the photodiode 104 region of the substrate 102 and expose the p-well region 140. An n-type dopant 152, e.g., phosphorus or arsenic, is implanted into the substrate 102 to form active areas proximate the gates 106, 108, 110, and 112, including the floating diffusion region 114 and source/drain regions 116, 118, and 120. The dopant implant 152 may also be angled with respect to the substrate 102 so the doped regions extend under the gates. Under the gates (106, 108, 110, and 112) and between the source/drain regions (116, 118, and 120) and photodiode (104) are the channel regions 115.

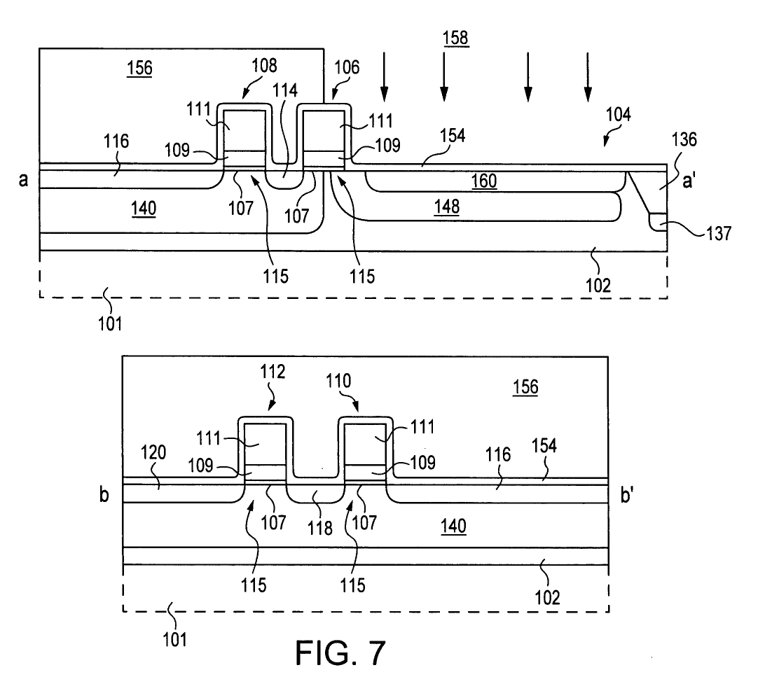

Now referring to FIG. 7, this figure shows the wafer cross-section shown in FIG. 6 at a subsequent stage of fabrication. The photoresist 150 is removed and an insulating spacer layer 154 is formed over the substrate 102 and gates 106, 108, 110, and 112. The insulating spacer layer 154 can be formed of TEOS or other similar dielectric materials. Over the insulating spacer layer 152 and the p-well 140 another photoresist mask 156 is formed; the photodiode 104 (FIG. 2) region of the substrate 102 is exposed. A p-type dopant 158, e.g., boron, is implanted into the substrate 102 to form a p-type region 160 at the substrate 102 surface above the n-type region 148 of the photodiode 104. This creates a p-n junction for photo-charge generation.

Now referring to FIG. 8, this figure shows the wafer cross-section shown in FIG. 7 at a subsequent stage of fabrication. After completing the photodiode 104, the photoresist 156 is removed. A thick insulating layer 162 is formed over the substrate 102, including the photodiode 104 and gates 106, 108, 110, and 112. This layer 162 should be transparent to light since it will cover the photodiode 104; it can be BPSG (Boro-Phospho-Silicate Glass) or another suitable material. The insulating layer 162 is planarized, preferably by CMP (chemical mechanical polishing) and patterned for etching, e.g., with photoresist (not shown).

Still referring to FIG. 8, vias 164 are formed through the insulating layer 162 and other intervening layers (e.g., spacer layer 154, insulating layer 111, etc.) by controlled etching (preferably by RIE dry etching as is known in the art) to expose the conductive layer 109 of the gates 106, 108, 110, and 112 where they overlie the channel regions 115 and to expose the substrate 102 surface at the floating diffusion region 114 and source/drain regions 116, 118, and 120. The etch is controlled so that etching stops at the conductive layer 109 of the gates 106, 108, 110, and 112 before the etch reaches the underlying gate oxide layer 107. The vias 164 formed by the etching are preferably between about 0.16 μm to about 0.20 μm wide to allow for at least 0.05 μm surround over the gates 106, 108, 110, and 112, which, as discussed above, are preferably at least about 0.30 μm wide.

Still referring to FIG. 8, the vias 164 are filled with a conductive material to form contacts 122, 124, 126, 128, 130, 132, and 134, preferably by a sputtering or chemical vapor deposition (CVD) technique, although other techniques can be used. The conductive material is preferably tungsten or titanium, which can be annealed to form a silicide at the polysilicon interface at the conductive layer 109 of the gates 106, 108, 110, and 112. The conductive material is next planarized by CMP, using the insulating layer 162 as a stop to leave a wafer cross-section as shown in FIG. 8. This may be followed by standard metallization layer and interconnect line formation (not shown).

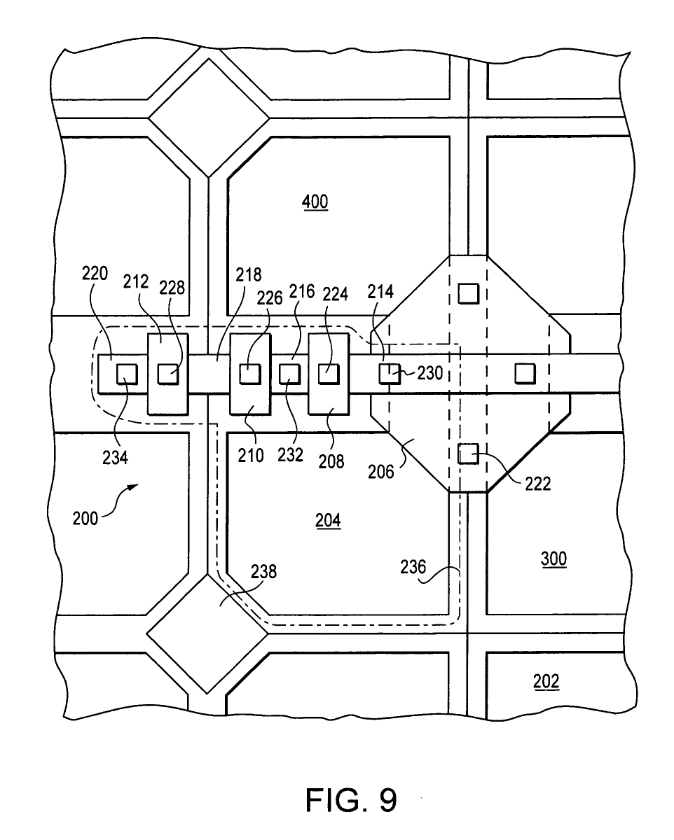

An alternative embodiment of the invention is shown in FIG. 9. While the same basic fabrication steps and techniques discussed above in relation to FIGS. 2-8 can be used to form the pixel 200 (defined by dotted-line surround) shown in FIG. 9, the features and elements of the pixel 200 are configured differently with respect to each other when compared to the layout of the pixel 100 of FIG. 2. FIG. 9 shows the pixel 200 configuration in an array of like pixels.

In FIG. 9, pixel 200 shares part of its circuitry components with other adjacent pixels 300 and 400. Each pixel 200, 300, and 400 has an individual photodiode; e.g., photodiode 204 of pixel 200. In this embodiment, the individual transfer gate is replaced by a transfer gate 206 shared between pixel 200 and pixel 300.

Preferably, the transfer gate 206 is angled with respect to the photodiode 204, as shown in FIG. 9. Here, the term “angled” means that a portion of the transfer gate 206 spans across a corner of the photodiode 204 as opposed to across its length or width, as discussed above in relation to the embodiment shown in FIG. 2. This preferred angled geometry of the transfer gate 206 allows for an efficient layout of the transfer gate 206. In addition, this angled layout is also beneficial in maximizing the fill factor of the pixel 200 by maximizing the area of the photodiode 204.

The remaining pixel components are shared by the adjacent pixels 200 and 400. These components include the floating diffusion region 214, which serves as a common storage node for the pixels 200 and 400. A reset gate 208 is located proximate the floating diffusion region 214. A source/drain region 216 is located on a second side of the reset gate 208 opposite the floating diffusion region 214 and is capable of receiving a supply voltage (Vₐₐ). The floating diffusion region 214 is also electrically connected to the source follower gate 210 (connection not shown), which has a source/drain 218. The source follower transistor having gate 210 outputs a voltage output signal from the floating diffusion region 214 to the row select transistor having gate 212. The row select transistor gate 212 has a source/drain 220 adjacent thereto for selectively reading out the pixel signal to a column line (not shown). In addition, a shared capacitor 238 is electrically connected to the floating diffusion region 214. The capacitor 238 can increase the charge storage capacity of the floating diffusion region 214.

The transistor gates 206, 208, 210, and 212, floating diffusion region 214, and source/drain regions 216, 218, and 220, have contacts 222, 224, 226, 228, 230, 232, and 234, respectively thereto. As with the pixel 100 shown in FIGS. 2 and 8 and described above, the contacts to the transistor gates 206, 208, 210, and 212 of the pixel 200 are directly over these gates and the active areas of the pixel 200. As with pixel 100 (FIG. 2), the location of the contacts 222, 224, 226, and 228 over the gates 206, 208, 210, and 212 enables the pixel 200 circuitry to be more densely packed, which allows for a relatively larger portion of the substrate 202 to be used for the photodiode 204.

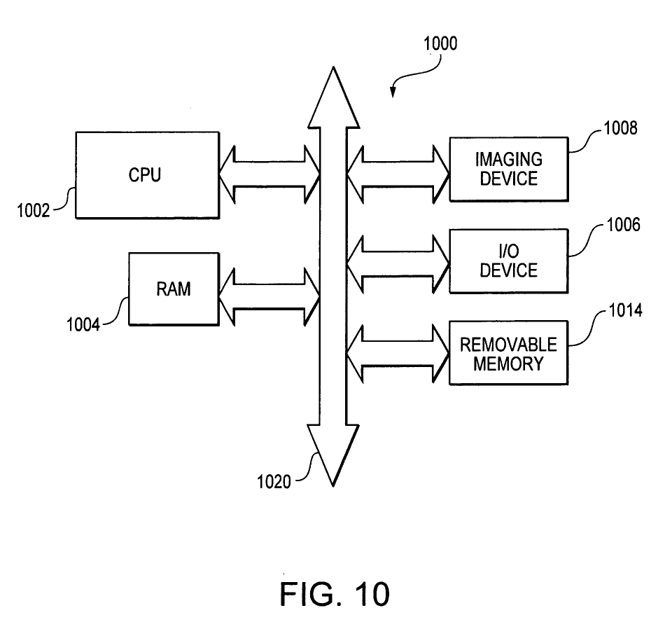

FIG. 10 shows a system 1000, a typical processor system modified to include an imaging device 1008 (such as an imaging device with pixels 100 or 200 as illustrated in FIGS. 2 and 9) of the invention. The processor system 1000 is exemplary of a system having digital circuits that could include image sensor devices. Without being limiting, such a system could include a computer system, camera system, scanner, machine vision, vehicle navigation, video phone, surveillance system, auto focus system, star tracker system, motion detection system, image stabilization system, and data compression system, and other systems employing an imager.

System 1000, for example a camera system, generally comprises a central processing unit (CPU) 1002, such as a microprocessor, that communicates with an input/output (I/O) device 1006 over a bus 1020. Imaging device 1008 also communicates with the CPU 1002 over the bus 1020. The processor-based system 1000 also includes random access memory (RAM) 1004, and can include removable memory 1014, such as flash memory, which also communicate with the CPU 1002 over the bus 1020. The imaging device 1008 may be combined with a processor, such as a CPU, digital signal processor, or microprocessor, with or without memory storage on a single integrated circuit or on a different chip than the processor.

Various embodiments of the invention have been described above. Although this invention has been described with reference to these specific embodiments, the descriptions are intended to be illustrative of the invention and are not intended to be limiting. Various modifications and applications may occur to those skilled in the art without departing from the spirit and scope of the invention as defined in the appended claims.

What is claimed as new and sought to be protected by letters patent is as follows:

1. An imager pixel, comprising:
a photoconversion device; and
a circuit configured to operate said photoconversion device, said circuit comprising transistor gates over channel regions, each of said gates having a respective contact to operate said transistor gates, wherein said transistor gates include a transfer gate and the contact to said transfer gate is over a channel region associated with said transfer gate.

2. The imager pixel of claim 1, wherein said transistor gates further comprise a reset gate, a source follower gate, and a row select gate.

3. The imager pixel of claim 1, wherein said photoconversion device is a photodiode.

4. The imager pixel of claim 1, wherein at least a portion of said circuit is shared with a second imager pixel.

5. The imager pixel of claim 1, wherein said pixel is a CMOS pixel.

6. The imager pixel of claim 1, wherein said transistor gates are at least about 0.30 μm wide.

7. The imager pixel of claim 1, wherein said transistor gates each have a gate electrode that is at least about 0.10 μm thick.

8. The imager pixel of claim 1, wherein said transistor gates each comprise a nitride or oxide etch stop layer.

9. The imager pixel of claim 1, wherein said transistor gates each comprise a silicide etch stop layer.

10. The imager pixel of claim 1, wherein each contact is about 0.16 μm to about 0.22 μm wide.

11. The imager pixel of claim 1, wherein each contact is over the respective transistor gate and associated channel region.

12. The imager pixel of claim 11, wherein each contact has at least about 0.05 μm surround by said respective transistor gate where said contact meets said respective transistor gate.

13. A CMOS imager device, comprising:
a substrate;
a photodiode in said substrate;
a charge storage region in said substrate;
a transfer gate configured to gate charge between said photodiode and said charge storage region;
a reset gate configured to reset said charge storage region;
a source follower gate configured to receive charge from said charge storage region;
a row select gate configured to couple said source follower gate to an output line; and
a respective contact plug to each of said transfer gate, reset gate, source follower gate, and row select gate, wherein each respective contact plug is provided over an active region.

14. The CMOS imager device of claim 13, wherein at least said transfer gate is shared with a second photodiode.

15. The CMOS imager device of claim 13, wherein at least said floating diffusion region, said reset gate, said source follower gate, and said row select gate are shared with a second photodiode.

16. The CMOS imager device of claim 13, wherein each gate is at least about 0.30 μm wide

17. The CMOS imager device of claim 13, wherein each gate has an electrode that is at least about 0.10 μm thick.

18. The CMOS imager device of claim 13, wherein each respective contact plug is about 0.16 μm to about 0.22 μm wide.

19. The CMOS imager device of claim 13, wherein device is part of an array of like devices.

20. The CMOS imager device of claim 13, wherein each of said respective contact plugs are over a respective channel region associated with said respective gate.

21. A method of forming an imager pixel, comprising:
providing a substrate;
forming a photoconversion device in said substrate;
providing a plurality of gates over channel regions in said substrate, said plurality of gates being configured to operate said imager pixel and including a transfer gate; and
forming contacts to each gate of said plurality of gates, wherein at least the contact to said transfer gate is over a respective one of said channel regions.

22. The method of claim 21, wherein said imager pixel is a CMOS imager pixel.

23. The method of claim 21, wherein said photoconversion device is a photodiode.

24. The method of claim 21, wherein said plurality of gates further comprises a reset gate, a source follower gate, and a row select gate.

25. The method of claim 21, wherein each gate is at least about 0.30 μm wide

26. The method of claim 21, wherein each gate has an electrode that is at least about 0.10 μm thick.

27. The method of claim 26, further comprising providing an etch stop layer over said gate electrode, said etch stop layer comprising a material selected from the group consisting of: nitrides, oxides, and suicides.

28. The method of claim 21, wherein each contact is about 0.16 μm to about 0.22 μm wide.

29. The method of claim 21, wherein each of said contacts is over a respective channel region.

30. A method of forming a CMOS imager pixel, comprising:
providing a substrate;
forming a photodiode in said substrate;
forming a transfer gate proximate said photodiode;
forming a reset gate proximate said photodiode;
forming a source follower gate proximate said photodiode;
forming a row select gate proximate said photodiode; and
forming a plurality of contact plugs to said gates, wherein at least a contact plug for said transfer gate is over a channel for said transfer gate.

31. The method of claim 30, wherein at least said transfer gate is shared with a second photodiode.

32. The method of claim 30, further comprising the step of forming a floating diffusion region in said substrate.

33. The method of claim 30, wherein at least said reset gate, said source follower gate, and said row select gate are shared by said photodiode with a second photodiode.

34. The method of claim 30, wherein each gate is at least about 0.30 μm wide

35. The method of claim 30, wherein each gate has an electrode that is at least about 0.10 μm thick.

36. The method of claim 30, wherein each contact plug is about 0.16 μm to about 0.22 μm wide.

37. The method of claim 30, wherein said CMOS imager pixel is formed as part of an array of like imager pixels.

38. The method of claim 30, wherein each said contact is formed over a respective channel region.

39. A method of forming an imager cell, comprising:
forming a photodiode in a substrate;
forming cell circuitry for reading and refreshing said imager cell; and
forming transistor gate contacts to said cell circuitry, wherein at least a contact to a transfer gate is over said transfer gate and a respective channel region.

40. The method of claim 39, wherein said act of forming cell circuitry further comprises forming a source follower transistor, and forming a row select transistor.

41. The method of claim 39 wherein said gate electrodes are at least about 0.10 μm thick.

42. The method of claim 39, wherein said gate electrodes are at least about 0.30 μm wide.

43. The method of claim 39, wherein said contacts are about 0.16 μm to about 0.22 μm wide.

44. The method of claim 39, wherein each said contact to a gate is formed over a respective channel region of said gate.

45. A processor system, comprising:
a processor and an imager coupled to said processor, said imager comprising an array of pixels, each pixel comprising:
a photoconversion device; and
a circuit configured to operate said photoconversion device, said circuit comprising transistor gates over channel regions, each of said gates having a respective contact to operate said transistor gates, wherein said transistor gates include a transfer gate and the contact to said transfer gate is over a channel region associated with said transfer gate.

46. The processor system of claim 45, wherein said transistor gates further comprise a reset gate, a source follower gate, and a row select gate.

47. The processor system of claim 45, wherein said photoconversion device is a photodiode.

48. The processor system of claim 45, wherein at least a portion of said circuit is shared with a second imager pixel.

49. The processor system of claim 45, wherein said pixel is a CMOS pixel.

50. The processor system of claim 45, wherein said transistor gates are at least about 0.30 μm wide.

51. The processor system of claim 45, wherein said transistor gates each have a gate electrode that is at least about 0.10 μm thick.

52. The processor system of claim 45, wherein each said contact is about 0.16 μm to about 0.22 μm wide.

53. The processor system of claim 45, wherein each said contact is over the respective transistor gate and associated channel region.

54. The processor system of claim 45, wherein each said contact has at least about 0.05 μm surround by said respective transistor gate where said contact meets said respective transistor gate.
